(19) United States
(12) Patent Application Publication
(10) Pub. No.: US 2010/0140797 A1
(43) Pub. Date: Jun. 10, 2010

(54) DEVICE MOUNTING BOARD AND METHOD OF MANUFACTURING THE BOARD, SEMICONDUCTOR MODULE AND METHOD OF MANUFACTURING THE MODULE

(76) Inventors: Yasuyuki YANASE, Osaka (JP); Koichi SAITO, Osaka (JP)

Correspondence Address: MCDERMOTT WILL & EMERY LLP, 600 13TH STREET, N.W., WASHINGTON, DC, 20005-3096, US

(21) Appl. No.: 12/626,810

(22) Filed: Nov. 27, 2009

(30) Foreign Application Priority Data
Nov. 28, 2008 (JP) 2008-305424

(51) Int. Cl. H01L 23/488; H05K 1/11; H01L 21/60; H05K 3/46

(52) U.S. Cl. 257/737; 174/261; 438/121; 156/150; 257/E23.023; 257/E21.506

(57) ABSTRACT

A device mounting board is provided with: an insulating resin layer; a wiring layer provided on one major surface of the insulating resin layer; and a bump electrode electrically connected to the wiring layer and configured to be projected from the wiring layer toward the insulating resin layer. The bump electrode has an approximately convex-shaped top surface and at least the peripheral area on the top surface thereof is curve-shaped.

### CROSS-REFERENCE TO RELATED APPLICATIONS

This application is based upon and claims the benefit of priority from the prior Japanese Patent Application No. 2008-305424, filed Nov. 28, 2008, the entire contents of which are incorporated herein by reference.

### BACKGROUND OF THE INVENTION

1. Field of the Invention

The present invention relates to a device mounting board and a method of manufacturing the board, a semiconductor module and a method of manufacturing the module, and a mobile device. In particular, the present invention relates to a device mounting board in which a semiconductor device can be mounted by a flip chip mounting method and a method of manufacturing the board, and a semiconductor module, etc., including the device mounting board.

2. Description of the Related Art

Recently, with the trend toward miniaturization and high performance of electronic devices, there is a demand for reduction in the size of semiconductor devices used in electronic devices. To achieve this, reduction in pitches between electrodes of semiconductor devices is indispensable; however, the reduction in pitches has been limited due to the largeness of a solder ball itself or generation of a bridge during a soldering process. Accordingly, there has been a limit in the miniaturization of electronic devices by reducing the pitches between externally-connecting electrodes. As a structure to overcome such limitation, a structure is known in which a semiconductor device is mounted on a metal plate via an insulating resin such as an epoxy resin, and the electrode of the semiconductor device is connected to a projection formed, as an electrode or a via, on a metallic foil with a paste.

In a conventional structure, however, a projection and a semiconductor device are jointed together by pressure-bonding the projection having a pointed tip against the electrode of the semiconductor device such that the tip of the projection is crushed. Therefore, a pressure is applied to the electrode of the semiconductor device when pressure-bonding the projection against the electrode, and hence there is a fear that the electrode of the semiconductor device may be damaged.

To deal with this, it can be considered that the top surface of the projection is made flat in order to avoid the damage of the electrode of the semiconductor device by reducing the pressure applied to the electrode. However, if the top surface of the projection is made flat, the insulating resin remains on a joint surface between the projection and the electrode of the semiconductor device when joining the projection to the electrode via the insulating resin, and hence there is a fear that connection reliability between the two is deteriorated.

One of the advantages of the present invention is that, in the structure in which a bump electrode provided integrally with a wiring layer and a device electrode provided in a semiconductor device are connected together, the connection reliability between the bump electrode and the device electrode can be improved.

An embodiment of the present invention relates to a device mounting board. The device mounting board comprises: an insulating resin layer; a wiring layer provided on one major surface of the insulating resin layer; and a bump electrode electrically connected to the wiring layer and configured to be projected from the wiring layer toward the insulating resin layer, wherein the bump electrode has an approximately convex-shaped top surface and at least the peripheral area on the top surface is curve-shaped.

In the above embodiment, the peripheral area may be curve-shaped such that the distance from the surface of the wiring layer on the side where the bump electrode is projected, becomes smaller toward the periphery of the area.

In the above embodiment, the bump electrode may include a projection connected to the wiring layer and at least one metallic layer laminated on the top surface of the projection. The surface of the outermost metallic layer opposite to the projection may be approximately convex-shaped, and at least the peripheral area on the surface may be curve-shaped.

In the above embodiment, the bump electrode may include two or more of the metallic layers, and the surface of the metallic layer that is in contact with the projection, opposite to the projection, may be approximately convex-shaped, and at least the peripheral area on the surface be curve-shaped.

Another embodiment of the present invention relates to a semiconductor module. The semiconductor module comprises: a device mounting board provided with an insulating resin layer, a wiring layer provided on one major surface of the insulating resin layer, and a bump electrode electrically connected to the wiring layer and configured to be projected from the wiring layer toward the insulating resin layer; and a semiconductor device provided with a device electrode connected to the bump electrode, in which the distance between the bump electrode and the device electrode in the peripheral area of a joint portion between the two electrodes, becomes gradually larger from the joint portion toward outside.

Yet another embodiment of the present invention relates to a mobile device. The mobile device is mounted with the semiconductor module according to the aforementioned embodiments.

Yet another embodiment of the present invention relates to a method of manufacturing a device mounting board. The method of manufacturing a device mounting board is a method of manufacturing a device mounting board in which an insulating resin layer and a wiring layer are laminated. The method comprises: preparing a metal plate for the wiring layer, on one major surface of which a projection is provided; and forming a bump electrode configured to have an approximately convex-shaped top surface by performing plating on a top surface of the projection under a condition in which a plating reaction in the peripheral area on the top surface is suppressed, with the use of a mask from which the top surface of the projection is opened, so that a metallic layer having a curved shape, the thickness of the peripheral area of which is thinner than that of the central area, is provided on the top surface.

Yet another embodiment of the present invention relates to a method of manufacturing a device mounting board. The method of manufacturing a device mounting board is a method of manufacturing a device mounting board in which an insulating resin layer and a wiring layer are laminated. The method comprises forming a bump electrode configured to have an approximately convex-shaped top surface, and configured such that at least the peripheral area on the top surface is curve-shaped, by isotropically over-etching one major surface of a metal plate, with the use of a resist laminated at a predetermined position on the one major surface of the metal plat as a mask.

Yet another embodiment of the present invention relates to a method of manufacturing a semiconductor module. The method of manufacturing a semiconductor module comprises: forming, on one major surfaces of a metal plate, a bump electrode configured to have an approximately convex-shaped top surface, and configured such that at least the peripheral area on the top surface is curve-shaped; pressure-bonding, via an insulating resin layer, the metal plate and a semiconductor device provided with a device electrode corresponding to the bump electrode, so that the bump electrode and the device electrode are joined together; and forming a wiring layer by selectively removing the metal plate.

In the press-bonding of the aforementioned embodiment, the bump electrode and the device electrode may be joined together in a way that the bump electrode penetrates the insulating resin layer to reach the surface of the device electrode, and a joint portion between the two electrodes expands from the central area of the joint portion toward the peripheral area thereof.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a schematic cross-sectional view illustrating the structure of a device mounting board and a semiconductor module according to Embodiment 1;

FIG. 2 is a partially enlarged schematic cross-sectional view illustrating the periphery of a bump electrode in FIG. 1;

FIGS. 3A to 3D are process sectional views illustrating a method of manufacturing the semiconductor module according to Embodiment 1;

FIGS. 4A to 4D are process sectional views illustrating a method of manufacturing the semiconductor module according to Embodiment 1;

FIGS. 5A to 5C are process sectional views illustrating a method of manufacturing the semiconductor module according to Embodiment 1;

FIGS. 6A and 6B are process sectional views illustrating a method of manufacturing the semiconductor module according to Embodiment 1;

FIGS. 7A and 7B are process sectional views illustrating a method of manufacturing the semiconductor module according to Embodiment 1;

FIGS. 8A to 8D are process sectional views illustrating a method of manufacturing a semiconductor module according to Embodiment 2;

FIGS. 9A to 9D are process sectional views illustrating a method of manufacturing a semiconductor module according to Embodiment 3;

FIGS. 10A to 10D are process sectional views illustrating a method of manufacturing a semiconductor module according to Embodiment 4;

FIGS. 11A to 11C are process sectional views illustrating a method of manufacturing the semiconductor module according to Embodiment 4;

FIG. 12 is a view illustrating the structure of a cell phone according to Embodiment 5; and

FIG. 13 is a partial cross-sectional view illustrating the cell phone in FIG. 12.

### DETAILED DESCRIPTION OF THE INVENTION

The invention will now be described by reference to the preferred embodiments. This does not intend to limit the scope of the present invention, but to exemplify the invention.

Hereinafter, the present invention will de described with reference to the drawings based on the preferred embodiments of the invention. The same or like components, members, or processes illustrated in each drawing are denoted by like reference numerals, and the duplicative descriptions will be appropriately omitted. The embodiments are not intended to limit the invention but to serve as particular examples thereof, and all features or combinations thereof described there are not always essential to the present invention.

### Embodiment 1

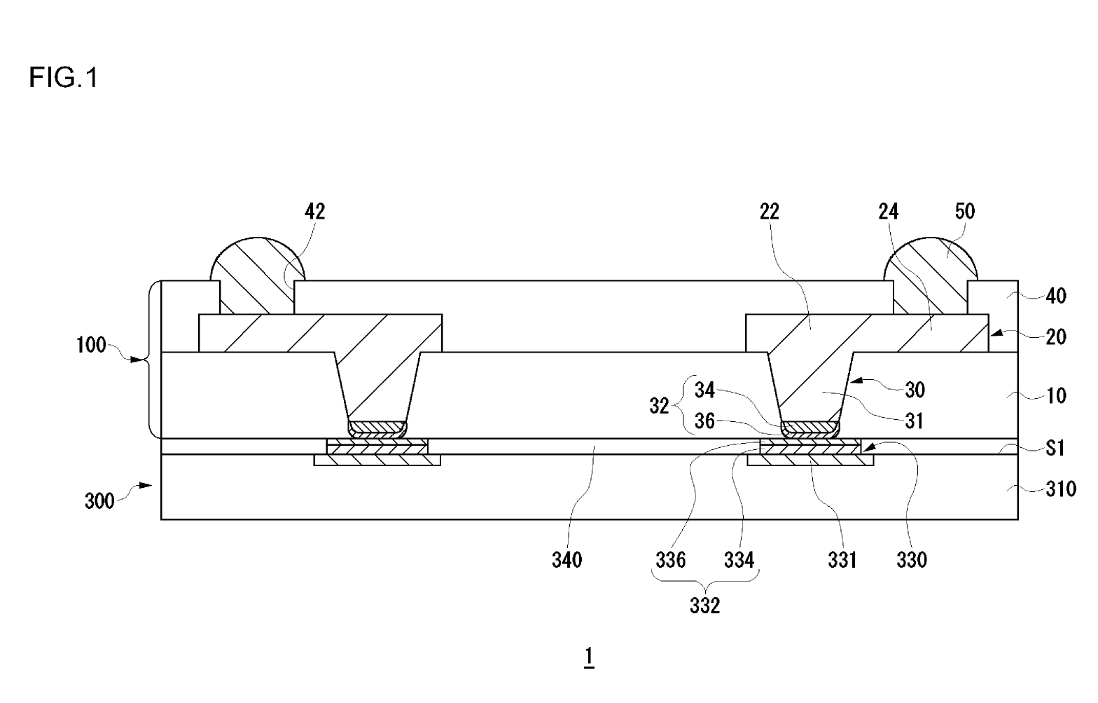

FIG. 1 is a schematic cross-sectional view illustrating the structure of a device mounting board 100 and a semiconductor module 1 according to Embodiment 1. The semiconductor module 1 has the structure in which a semiconductor device 300 is flip-chip connected to the device mounting board 100.

The semiconductor device 300 includes a semiconductor substrate 310, a device electrode 330 and a device protective layer 340.

The semiconductor substrate 310 is, for example, a P-type silicon wafer. An integrated circuit (IC) or a large scale integrated circuit (LSI) (not illustrated) is formed on the major surface S1 (upper surface in FIG. 1) of the semiconductor substrate 310 by a known technique.

The device electrode 330 connected to an IC is provided on the major surface S1, which is to be a mounting surface. The device electrode 330 includes an electrode 331 and a metallic layer 332 laminated on the surface of the electrode 331. A metal such as aluminum (Al) or copper (Cu) is used as a material of the electrode 331. The metallic layer 332 includes a nickel (Ni) layer 334 made of Ni, which is in contact with the electrode 331, and a gold (Au) layer 336 made of Au, which is laminated on the Ni layer 334, and hence the metallic layer 332 consists of the Ni/Au layers.

On the major surface S1 of the semiconductor substrate 310, a device protective layer 340 is formed such that the metallic layer 332 is exposed. A silicon oxide film (SiO₂), a silicon nitride film (SiN) or a polyimide (PI) film, etc. is preferably used as the device protective layer 340.

The device mounting board 100 comprises: an insulating resin layer 10; a wiring layer (rewiring layer) 20 provided on one major surface of the insulating resin layer 10; and a bump electrode 30 electrically connected to the wiring layer 20 and configured to be projected from the wiring layer 20 toward the insulating resin layer 10.

The insulating resin layer 10 is made of an insulating resin and serves as an adhesion layer between the wiring layer 20 and the semiconductor device 300. An insulating material that undergoes plastic flow by, for example, application of pressure, is used as the insulating resin layer 10.

An example of an insulating material that undergoes plastic flow due to application of pressure, includes an epoxy thermosetting resin. The epoxy thermosetting resin used for the insulating resin layer 10 only has to have a viscosity property of approximately 1 kPa·s under the condition in which, for example, temperature is approximately 160° C. and pressure is approximately 8 Mpa. In the epoxy thermosetting resin, the viscosity thereof falls to approximately one-eighth, comparing the case where the resin is applied with a pressure of approximately 5 Mpa to approximately 15 Mpa under the condition in which, for example, temperature is approximately 160° C., with the case where the resin is not applied with a pressure. Contrary to this, under the condition in which temperature is equal to or lower than the glass transition temperature Tg, the epoxy resin at B stage prior to thermal curing, does not have viscosity even when applied with a pressure, to the same extent as the case where the resin is not applied with a pressure. The thickness of the insulating resin layer 10 is, for example, approximately 45 μm.

The wiring layer 20 is provided on the major surface of the insulating resin layer 10 opposite to the semiconductor device 300. The wiring layer 20 is formed of a conductive material, preferably a rolled metal, more preferably a rolled copper. The rolled copper is strong in terms of mechanical strength, and hence is excellent as a material for rewiring, in comparison with a metallic film consisting of copper formed by plating, etc. The wiring layer 20 may be formed of electrolytic copper, etc. The wiring layer 20 has an electrode formation area 22 and a wiring area 24 extending continuously from the electrode formation area 22. The thickness of the wiring layer 20 is, for example, approximately 20 μm.

In the electrode formation area 22, the bump electrode 30 penetrating the insulating resin layer 10 is provided in a projected manner at a position corresponding to the position of the device electrode 330 of the semiconductor device 300. In the present embodiment, because the wiring layer 20 and the bump electrode 30 are integrally formed together, the connection between the wiring layer 20 and the bump electrode 30 is secured. Further, because the wiring layer 20 and the bump electrode 30 are integrally formed together, a crack or the like at the interface between the two, occurring due to a thermal stress generated in the usage environment of the semiconductor module 1, can be prevented. Further, because the electrical connection between the wiring layer 20 and the device electrode 330 is performed concurrently with the pressure-bonding between the bump electrode 30 and the device electrode 330, there is an advantage that the number of processes is not increased. A land area in which a solder ball 50, which will be described later, is arranged, and which concurrently serves as wiring, is formed in the end area of the wiring area 24.

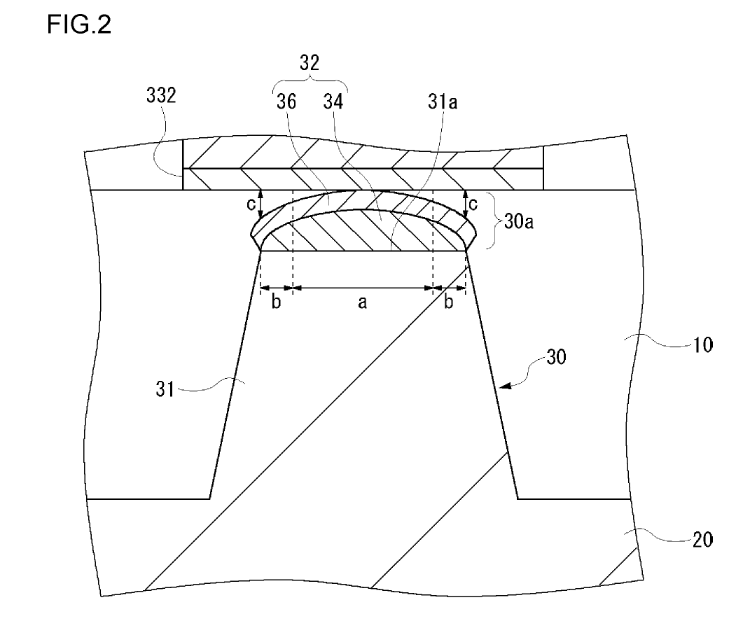

The bump electrode 30 has an approximately convex-shaped top surface, and at least the peripheral area on the top surface thereof is curve-shaped. Hereinafter, the shape of the bump electrode 30 will be described in detail with reference to FIG. 2. FIG. 2 is a partially enlarged schematic cross-sectional view illustrating the periphery of the bump electrode 30 in FIG. 1.

As illustrated in FIG. 2, the bump electrode 30 projected from the wiring layer 20 toward the insulating resin layer 10 has an approximately convex-shaped top surface 30a. At least the peripheral area b on the top surface 30a is curve-shaped, in which the distance from the surface of the wiring layer 20 on the side where the bump electrode 30 is projected (upper surface in FIG. 1), becomes smaller toward the periphery of the area. That is, the top surface 30a of the bump electrode 30 has a curved shape whose side turns toward the wiring layer 20, in a cross-sectional view including the central axis of the bump electrode 30; and the top of the bump electrode 30 is dome-shaped. Accordingly, the distance c between the bump electrode 30 and the device electrode 330 in the peripheral area (approximately equal to the peripheral area b of the top surface 30a) of the joint portion between the two electrodes (approximately equal to the central area a of the top surface 30a), become gradually larger from the joint portion toward outside. At least the center of the central area a of the top surface 30a has an approximately flat surface parallel to the metallic layer 332, by the joint with the metallic layer 332, which will be described later.

In the present embodiment, the bump electrode 30 consists of a projection 31 formed integrally with the wiring layer 20, and a metallic layer 32 laminated on the top surface 31a of the projection 31. The metallic layer 32 includes a nickel (Ni) layer 34 made of Ni, which is in contact with the projection 31, and a gold (Au) layer 36 made of Au, which is laminated on the Ni layer 34, and hence the metallic layer 32 consists of the Ni/Au layers. In the Ni layer 34 in contact with the projection 31, the thickness of the peripheral area thereof is thinner than that of the central area thereof, and hence the surface opposite to the projection 31 is approximately convex-shaped, and at least the peripheral area on the surface is curve-shaped. Therefore, also in the Au layer 36 laminated on the Ni layer 34, the surface thereof is approximately convex-shaped, and at least the peripheral area on the surface is curve-shaped. The number of the layers of the metallic layer 32 should not be particularly limited, but the metallic layer 32 may have at least one layer. In the present embodiment, the metallic layer 32 is laminated on the top surface 31a of the projection 31 in the bump electrode 30; and the metallic layer 332 is laminated on the electrode 331 in the device electrode 330. The bump electrode 30 and the device electrode 330 are electrically connected by Au—Au bonding between the metallic layers 32 and 332. The bump electrode 30 and the device electrode 330 may be directly connected together. The diameters of the tip (top surface) and the base surface of the bump electrode 30 are, for example, approximately 45 μmφ and approximately 60 μmφ, respectively. The heights of the bump electrode 30 and the projection 31 are, for example, approximately 45 μm and approximately 40 μm, respectively. The thicknesses of the Ni layer 34 and the Au layer 36 are, for example, approximately 1 μm to approximately 15 μm and approximately 0.03 μm to approximately 1 μm, respectively.

Referring back to FIG. 1, a protective layer 40 for preventing oxidization of the wiring layer 20, etc. is provided on the major surface of the wiring layer 20 opposite to the insulating resin layer 10. Examples of the protective layer 40 include a solder resist layer etc. An opening 42 is formed in a predetermined area of the protective layer 40, and the land area of the wiring layer 20 is exposed by the opening 42. The solder ball 50 is formed within the opening 42 as an externally-connecting electrode, and the solder ball 50 and the wiring layer 20 are electrically connected together. A position where the solder ball 50 is formed, namely an area where the opening 42 is to be formed, in other words, the land area of the wiring layer 20, is located, for example, at the end where the rewiring (wiring layer 20) is put around. The thickness of the protective layer 40 is, for example, approximately 30 μm.

In the aforementioned descriptions with respect to the embodiment based on FIG. 2, the case where the metallic layer 32 consisting of a plating film is formed on the whole top surface 31a of the projection 31 in the bump electrode 30, has been described. However, the present invention should not limited thereto, but the metallic layer 32 may be formed so as to cover the top surface 31a and the side wall of the projection 31, or be formed on only part of the top surface 31a thereof. Even in these cases, the advantage peculiar to the present application can be exhibited.

### (Method of Manufacturing Device Mounting Board and Semiconductor Module)

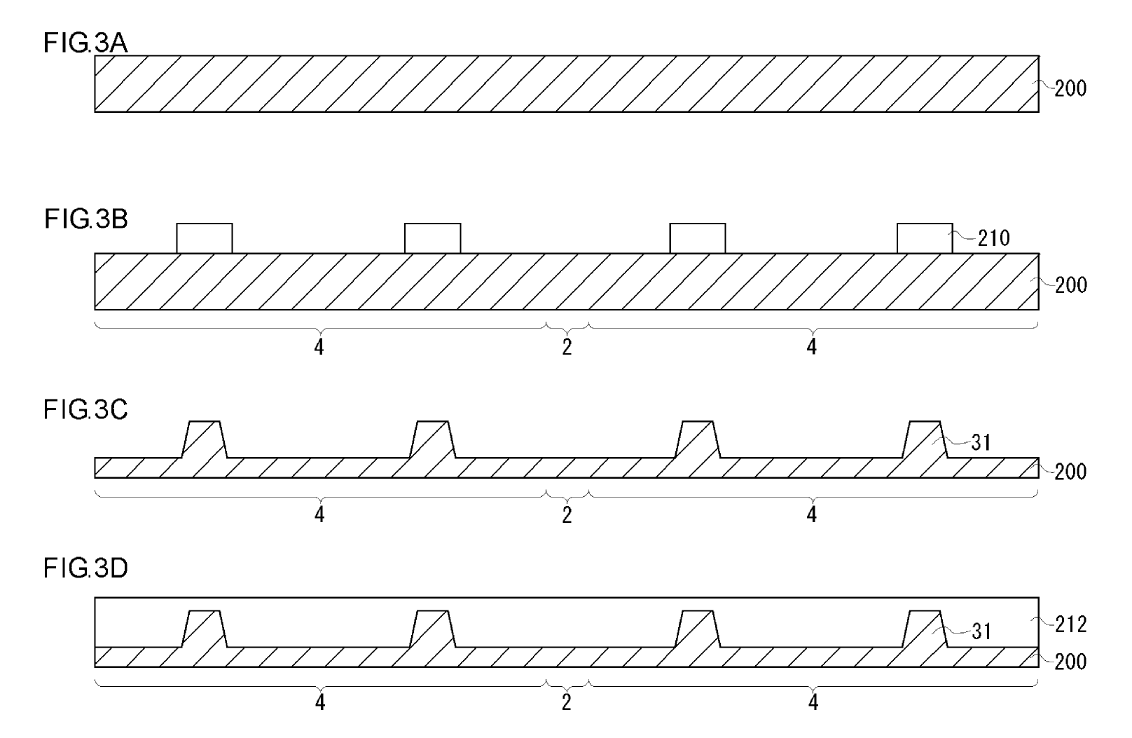

A method of manufacturing the semiconductor module according to Embodiment 1 will be described with reference to FIGS. 3A to 7B. FIGS. 3A to 7B are process sectional views illustrating the method of manufacturing the semiconductor module according to Embodiment 1.

As illustrated in FIG. 3A, a copper plate 200 having a thickness larger than at least a total of the height of the projection 31 in the bump electrode 30 and the thickness of the wiring layer 20 as illustrated in FIG. 1, is at first prepared as a metal plate. A rolled metal made of a rolled copper is adopted as the copper plate 200.

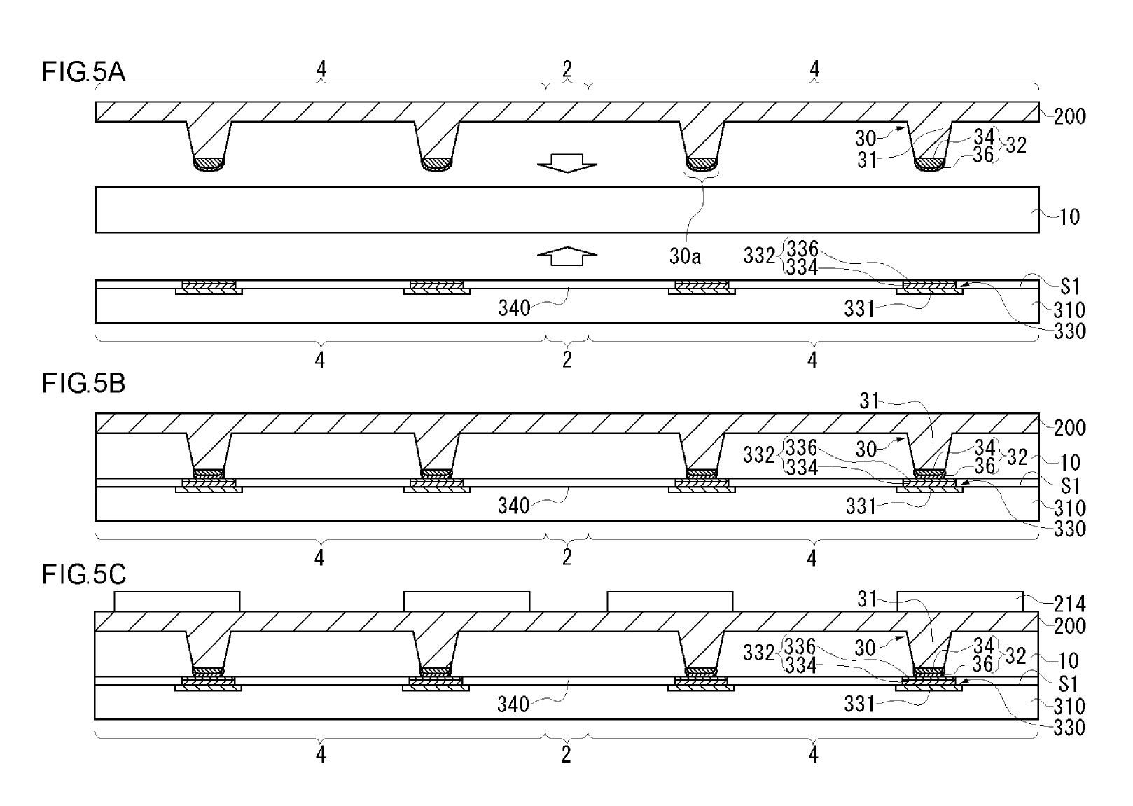

Subsequently, as illustrated in FIG. 3B, a resist 210 is selectively formed on one major surface of the copper plate 200 by a photolithographic method in line with a pattern corresponding to the bump electrode 30 formation areas. Herein, the array of the bump electrode 30 formation areas corresponds to the positions of the respective device electrodes 330 (see FIGS. 1 and 5A) in the semiconductor substrate 310 defined into a plurality of semiconductor module formation areas 4 by a plurality of scribe lines 2 (lines for dividing the semiconductor substrate 310 in a later process). Specifically, the resist 210 is selectively formed on the copper plate 200 by attaching a resist film having a predetermined thickness to the copper plate 200 by using a laminator device to exposing the resist film with a photomask having the pattern of the bump electrodes 30, and then by developing the resist film. In order to improve the adhesion with the resist, it is preferable that the surface of the copper plate 200 is subjected to pretreatments such as polishing and washing prior to lamination of the resist film, if necessary.

Subsequently, as illustrated in FIG. 3C, the projection 31 having a predetermined truncated cone pattern, projected from the surface of the copper plate 200, is formed by performing wet-etching using a chemical such as a ferric chloride solution, with the use of the resist 210 as a mask. In this case, the projection 31 is formed so as to have a tapered side surface, the diameter (size) of which becomes smaller toward the tip thereof. After the projection 31 is formed, the resist 210 is peeled off with a parting agent.

By the processes described above, the projection 31 is formed integrally with the copper plate 200. Alternatively, a metal mask such as silver (Ag) may be adopted instead of the resist 210. In this case, because the etching selectivity with the copper plate 200 is sufficiently secured, the patterning of the bump electrodes 30 can be further refined.

Subsequently, as illustrated in FIG. 3D, a plating-resistant resist 212 is laminated on the major surface of the copper plate 200 on the side where the projection 31 is formed, so that the projection 31 is buried. It is preferable that a resist protective film (not illustrated) is formed on the whole surface of the copper plate 200 opposite to the surface (lower-side surface) where the resist 212 is provided to protect the copper plate 200.

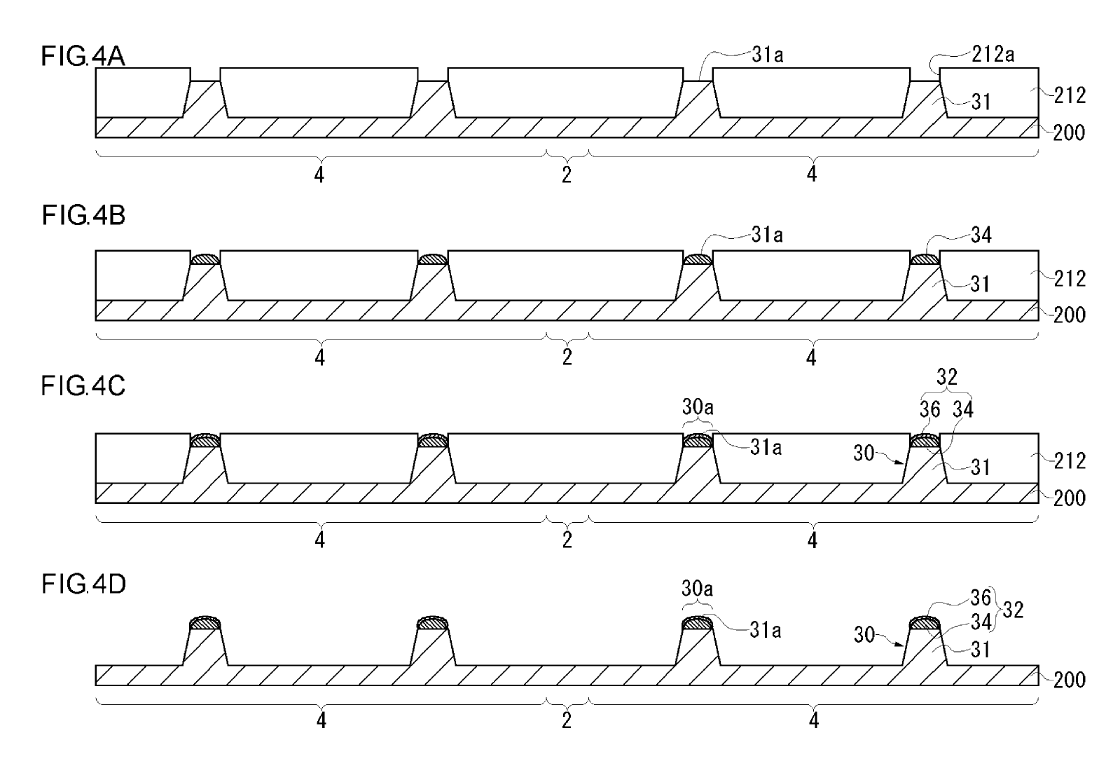

Subsequently, as illustrated in FIG. 4A, an opening 212a is formed by a lithographic method such that the top surface 31a of the projection 31 is exposed.

Subsequently, as illustrated in FIG. 4B, the Ni layer 34 is formed, as a metallic layer, on the top surface 31a exposed from the opening 212a by, for example, an electrolytic plating method or an electroless plating method with the use of the resist 212 as a mask. The electrolytic plating and the electroless plating are performed under the condition in which a plating reaction in the peripheral area on the top surface 31a of the projection 31 is suppressed. Specifically, the electroless plating is performed under the condition in which the reactivity in the peripheral area is further reduced by containing a larger amount of a stabilizer component, contained in a plating solution and functioning to adjust the plating reaction, than usual, as well as the use of the fact that the stabilizer component is likely to adhere to the peripheral area of the opening. On the other hand, the electrolytic plating is performed under the current density condition in which a film formation rate in the longitudinal direction is higher, as well as the use of the fact that the reactivity in the peripheral area of the opening is inferior to that in the central area because the plating solution is difficult to circulate in the peripheral area. Thereby, the Ni layer 34 having a curved shape, the thickness of the peripheral area of which is smaller than that of the central area, is formed on the top surface 31a of the projection 31.

Subsequently, as illustrated in FIG. 4C, the Au layer 36 is formed, as a metallic layer, on the surface of the Ni layer 34 exposed from the opening 212a, by, for example, the electrolytic plating method or the electroless plating method with the use of the resist 212 as a mask. The electrolytic plating or the electroless plating in this case is performed under a usual reaction condition, that is, a condition in which plating reactions almost equivalent to each other are generated in the central area and the peripheral area. Therefore, the Au layer 36 having an approximately uniform thickness across the central area and the peripheral area, is formed on the surface of the Ni layer 34. Thereby, the metallic layer 32 consisting of the Ni/Au layers is formed on the projection 31, allowing the bump electrode 30 having an approximately convex-shaped top surface to be completed.

Subsequently, as illustrated in FIG. 4D, the resist 212 is peeled off with a parting agent. The bump electrode 30 is formed integrally with the copper plate 200 by the processes described above. If necessary, the copper plate 200 is processed to be thinner by etch-backing the surface of the copper plate 200 opposite to the side where the bump electrode 30 is provided, with the use of wet-etching using a chemical such as a ferric chloride solution. In this case, a resist protective film (not illustrated) is formed on the major surface of the copper plate 200 on the side where the bump electrode 30 is formed to protect the bump electrode 30 and the copper plate 200, the resist protective film being removed after the etching is performed. Thereby, the thickness of the copper plate 200 can be adjusted to a predetermined thickness (thickness of the wiring layer 20).

Subsequently, as illustrated in FIG. 5A, the semiconductor substrate 310 (6-inch semiconductor wafer) is prepared, on the major surface S1 of which the semiconductor module formation areas 4 having the device electrodes 330 and the device protective layer 340 are formed, the areas 4 being defined by the scribe lines 2. FIG. 5A illustrates two semiconductor devices. Specifically, with respect to each of the semiconductor module formation areas 4 in the semiconductor substrate 310 such as a p-type silicon substrate, a predetermined IC and the electrode 331 of the device electrode 330 located at the outer periphery of the IC, are formed on the major surface S1 by using a semiconductor manufacturing process combined with known techniques such as lithographic technique, etching technique, ion implantation technique, film formation technique and heat treatment technique. The insulating device protective layer 340 is formed on the major surface S1 of the semiconductor substrate 310 excluding these electrodes 331, and the metallic layer 332 consisting of the Ni layer 334 and the Au layer 336 is laminated on the electrodes 331, thereby completing the device electrode 330.

As illustrated in FIG. 5A, the copper plate 200, the insulating resin layer 10 and the semiconductor substrate 310 (semiconductor device 300) are arranged between a pair of flat plates (not illustrated) of which a press apparatus is composed. The copper plate 200 is arranged on one major surface of the insulating resin layer 10 such that the bump electrode 30 is directed toward the insulating resin layer 10, and the semiconductor substrate 310 is arranged on the other major surface thereof. In this case, positions of the metallic layers 32 and 332, corresponding to each other, are matched together. The flat plate is formed of, for example, SiC. The copper plate 200 and the semiconductor substrate 310 are then pressure-bonded together via the insulating resin layer 10 with the press apparatus. The pressure and the temperature at the press process are approximately 5 Mpa and 200° C., respectively.

The insulating resin layer 10 undergoes plastic flow due to the press process, causing the bump electrode 30 to penetrate the insulating resin layer 10. The tip of the top surface 30a of the bump electrode 30 then reaches the surface of the device electrode 330 (surface of the Au layer 36) such that the two are jointed together. The two are further pressure-bonded, causing the top surface 30a of the bump electrode 30 to deform by the pressure from the device electrode 330. Thereby, the joint portion between the two extends from the central area toward the is peripheral area. As a result, as illustrated in FIG. 5B, the copper plate 200, the insulating resin layer 10 and the semiconductor substrate 310 (semiconductor device 300) are integrated together, allowing the bump electrode 30 and the device electrode 330 to be electrically connected.

The insulating resin layer 10 is made of an insulating material that undergoes plastic flow by a pressure, and the bump electrode 30 is shaped such that the diameter of the side surface thereof becomes smaller toward the tip of the electrode 30, and hence the bump electrode 30 smoothly penetrates the insulating resin layer 10. Further, because the top surface 30a of the bump electrode 30 is approximately convex-shaped and the peripheral area thereof is curve-shaped, the insulating resin layer 10 between the bump electrode 30 and the device electrode 330 is pushed out of the central area of the joint portion to the peripheral area thereof, as the joint portion extends from the central area to the peripheral area. As a result, in a state where the device mounting board 100, the insulating resin layer 10 and the semiconductor device 300 are integrated together in this order, the residue of the insulating resin layer 10 is suppressed from lying between the bump electrode 30 and the device electrode 330, allowing the connection reliability to be improved. In the present embodiment, the insulating resin layer 10 is laminated on the major surface of the copper plate 200 on the side where the bump electrode 30 is formed, by pressure-bonding the copper plate 200 to the insulating resin layer 10.

Subsequently, as illustrated in FIG. 5C, a resist 214 having a pattern corresponding to the wiring layer 20 formation areas, is selectively formed on the surface of the copper plate 200 opposite to the insulating resin layer 10, by using the photolithographic technique.

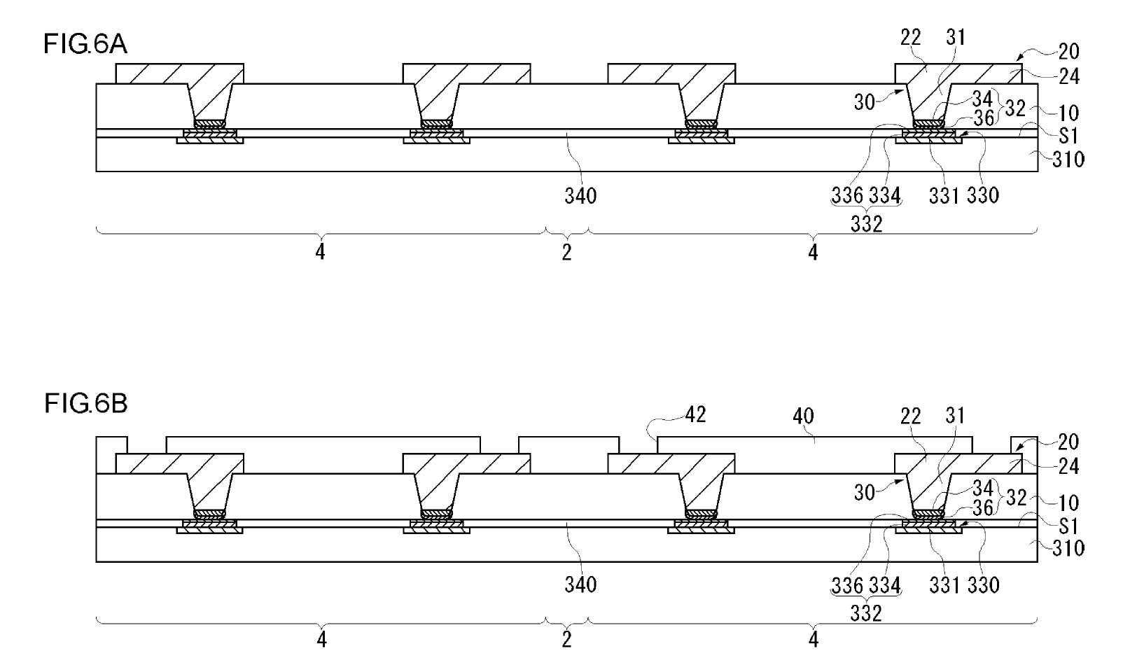

Subsequently, as illustrated in FIG. 6A, the wiring layer 20 (rewiring) is formed by processing the copper plate 200 into a predetermined pattern by using the etching technique, with the use of the resist 214 as a mask. The wiring layer 20 has the electrode formation area 22 where the bump electrode 30 is formed, and the wiring area 24 extending continuously from the area 22. The resist 214 is peeled off after the wiring layer 20 is formed.

Subsequently, as illustrated in FIG. 6B, after the protective layer (photo solder resist layer) 40 is laminated on the wiring layer 20 and the insulating resin layer 10, the opening 42 is formed in a predetermined area (solder ball-mounted area) of the protective layer 40 with the photolithographic method.

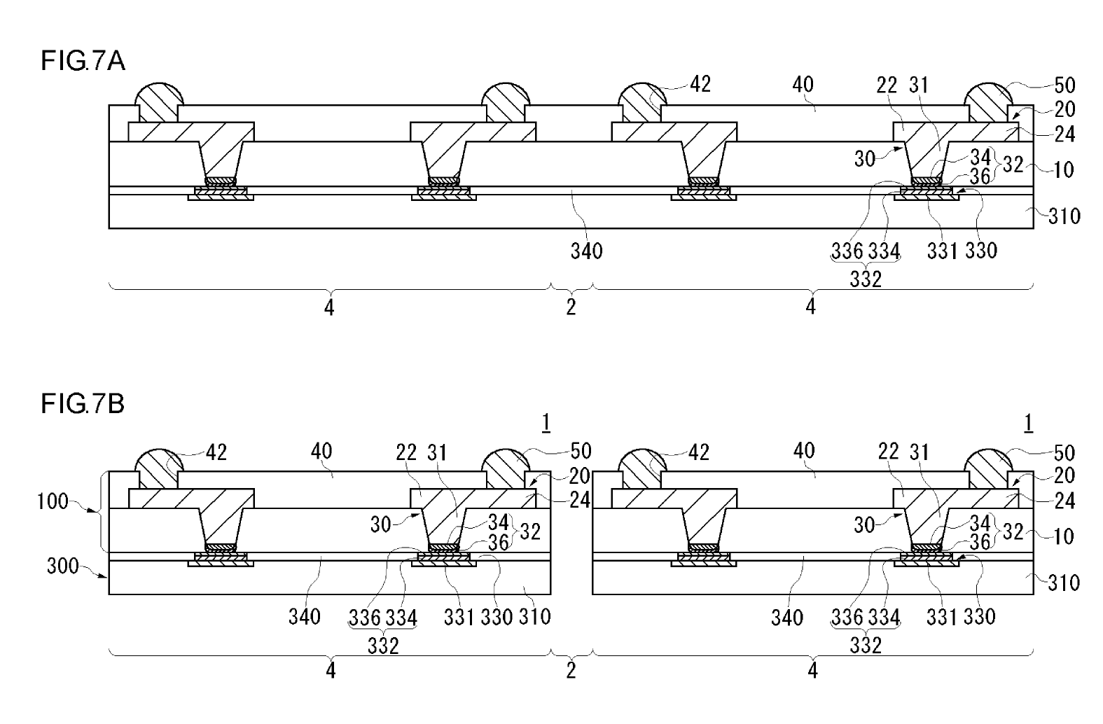

Subsequently, as illustrated in FIG. 7A, the solder ball 50 is mounted in the opening 42 of the protective layer 40 with the screen printing method. Specifically, the solder ball 50 is formed by printing a solder paste in which a resin and a solder material are processed into a paste, onto a desired position by the screen mask, and then by heating the paste to the solder melting temperature.

Subsequently, as illustrated in FIG. 7B, the semiconductor substrate 310 is individuated into a plurality of semiconductor modules 1 by dicing the substrate 310 from the underside (lower surface side) of the substrate 310, along the scribe lines 2 defining a plurality of semiconductor module formation areas 4. Thereafter, the residue generated during the dicing is removed by washing the individuated semiconductor module 1 with the use of a chemical. The semiconductor module 1 can be manufactured by the processes described above. When the semiconductor substrate 310 (semiconductor device 300) is not mounted, the device mounting board 100 can be obtained.

To sum up the operation and effect by the aforementioned structure, in the device mounting board 100 according to Embodiment 1, the device mounting board 100 comprises the bump electrode 30 that has an approximately convex-shaped top surface 30a and at least the peripheral area b on the top surface 30a is curve-shaped. Therefore, in the case where the device mounting board 100 and the semiconductor substrate 310 (semiconductor device 300) are pressure-bonded together via the insulating resin layer 10 such that the bump electrode 30 penetrates the insulating resin layer 10 to be joined to the device electrode 330, the residue of the insulating resin layer 10 is suppressed from lying between the bump electrode 30 and the device electrode 330. Therefore, the connection reliability between the bump electrode 30 and the device electrode 330 can be improved. And thereby, the connection reliability between the device mounting board 100 and the semiconductor device 300 can be improved.

Further, because the top surface 30a of the bump electrode 30 is approximately convex-shaped, and at least the peripheral area thereof is curve-shaped, the pressure applied to the device electrode 330 when the bump electrode 30 and the device electrode 330 are pressure-bonded together, can be reduced. Thereby, damage of the device electrode 330 can be avoided, allowing the connection reliability between the device mounting board 100 and the semiconductor device 300 to be improved. Further, because destruction of the semiconductor device 300 can be prevented, the production yield of the semiconductor module 1 can be increased, allowing the production cost of the semiconductor module 1 to be reduced.

### Embodiment 2

In the aforementioned Embodiment 1, the semiconductor module 1 is formed by pressure-bonding the copper plate 200 and the semiconductor substrate 310 (semiconductor device 300) together via the insulating resin layer 10; however, the semiconductor module 1 may be formed in the following process. Hereinafter, the present embodiment will be described. The basic structure of the semiconductor module 1 and the manufacturing process of the bump electrode 30 are basically the same as the Embodiment 1. Therefore, the same structures as Embodiment 1 shall be denoted by the same reference numerals, and the duplicative explanations will be omitted appropriately, and descriptions will be made focusing on the structures different from Embodiment 1.

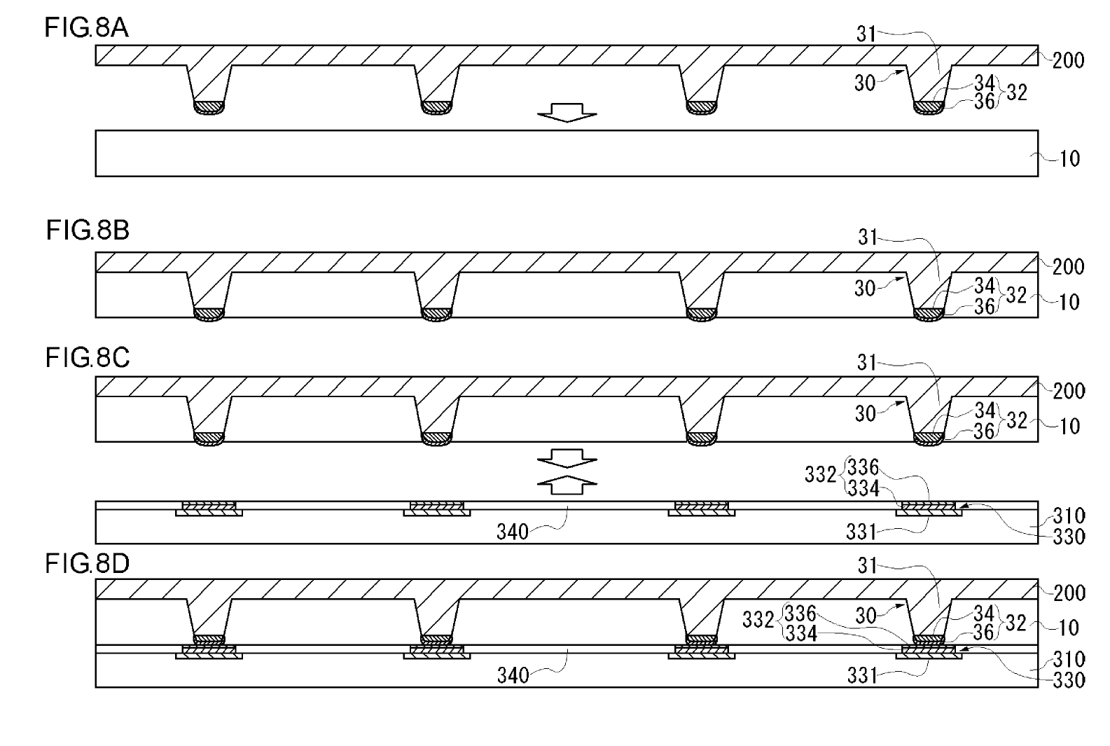

FIGS. 8A to 8D are process sectional views illustrating a method of manufacturing a semiconductor module according to Embodiment 2.

As illustrated in FIG. 8A, the copperplate 200 with which the bump electrode 30 covered by the metallic layer 32 is integrally formed, is prepared by the same processes as those illustrated in FIGS. 3A to 3D and FIGS. 4A to 4D. The insulating resin layer 10 is then laminated on the surface of the copperplate 200 on the side where the bump electrode 30 is provided.

Subsequently, as illustrated in FIG. 8B, the insulating resin layer 10 is processed to be thinner by using the O₂ plasma etching technique, etc., such that the metallic layer 32 provided on the top surface of the bump electrode 30 is exposed. In the present embodiment, Au of which the Au layer 36 is composed is exposed as the surface of the metallic layer 32.

Subsequently, as illustrated in FIG. 8C, the copper plate 200 on which the insulating resin layer 10 is laminated, and the semiconductor substrate 310 are arranged such that the bump electrode 30 and the device electrode 330 face each other, and then the copper plate 200 and the semiconductor substrate 310 are pressure-bonded together with a press apparatus. Thereby, as illustrated in FIG. 8D, the copper plate 200, the insulating resin layer 10 and the semiconductor substrate 310 are integrated together, and the bump electrode 30 and the device electrode 330 are pressure-bonded, allowing the two to be electrically connected.

Thereafter, in the same processes as those in Embodiment 1, the wiring layer 20 is formed; the protective layer 40 is laminated; the solder ball 50 is provided; and the semiconductor substrate is individuated into the semiconductor modules 1. The semiconductor module 1 can be manufactured by the processes described above.

As stated above, in addition to the aforementioned advantages in Embodiment 1, the following advantage can be further obtained by Embodiment 2. That is, in the present embodiment, the metallic layer 32 is exposed from the insulating resin layer 10, and hence the copper plate 200 and the semiconductor substrate 310 (semiconductor device 300) can be accurately positioned when pressure-bonding the two. Accordingly, the connection reliability between the bump electrode 30 and the device electrode 330 can be improved, eventually allowing the connection reliability between the device mounting board 100 and the semiconductor device 300 to be improved.

### Embodiment 3

In the aforementioned Embodiment 1, the metallic layer 32 consists of multiple layers, and the surface of the Ni layer 34, which is in contact with the projection 31, is approximately convex-shaped and the peripheral area of the surface is curve-shaped; however, among the metallic layer 32, the surface of another layer may be approximately convex-shaped. Hereinafter, the present embodiment will be described. The basic structure of the semiconductor module 1 is basically the same as the Embodiment 1. Therefore, the same structures as Embodiment 1 shall be denoted by the same reference numerals, and the duplicative explanations will be omitted appropriately, and descriptions will be made focusing on the structures different from Embodiment 1.

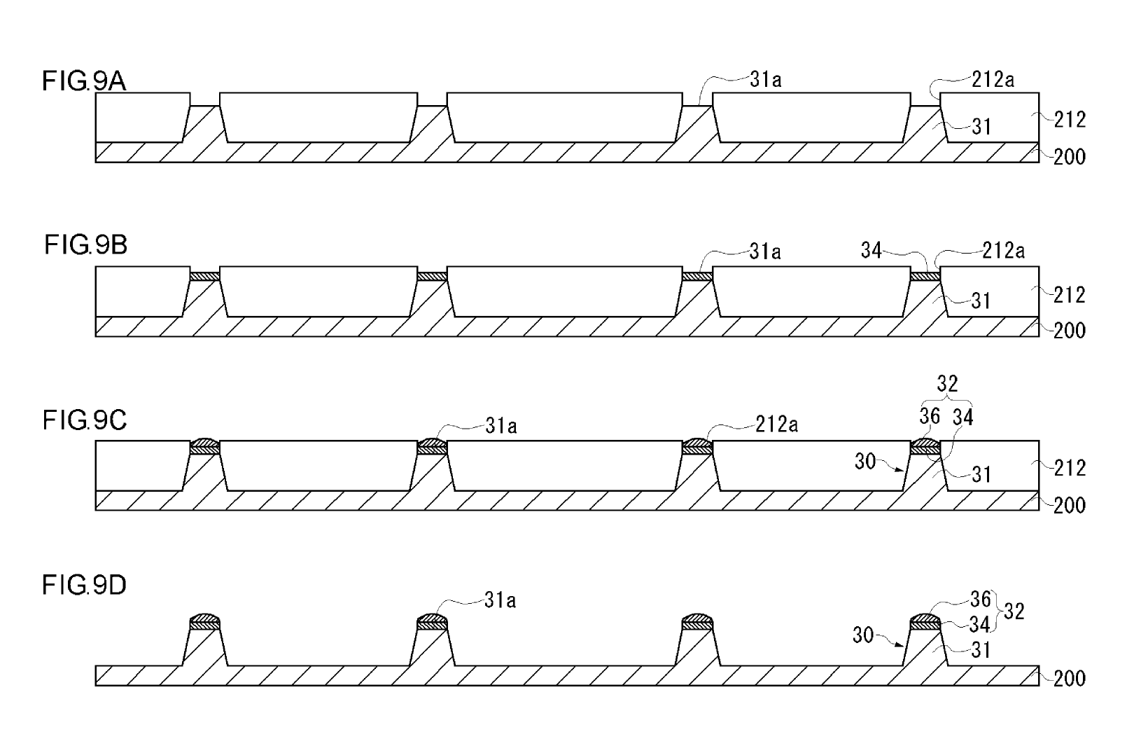

FIGS. 9A to 9D are process sectional views illustrating a method of manufacturing a semiconductor module according to Embodiment 3.

As illustrated in FIG. 9D, the bump electrode 30 according to the present embodiment includes the projection 31 and the metallic layer 32, the metallic layer 32 consisting of the Ni layer 34 and the Au layer 36. The Ni layer 34 has an approximately uniform thickness across the central area and the peripheral are. The surface of the Ni layer 34 opposite to the projection 31 is a flat surface approximately parallel to the top surface 31a of the projection 31. On the other hand, in the Au layer 36, the thickness of the peripheral area thereof is thinner than that of the central area thereof; and the surface of the Au layer 36 opposite to the Ni layer 34 is approximately convex-shaped, and at least the peripheral area on the surface is curve-shaped.

Subsequently, a method of manufacturing the semiconductor module 1 that has the bump electrode 30 having the aforementioned shape, will be described. As illustrated in FIG. 9A, the copper plate 200 is at first prepared in which the projection 31 is formed by the same processes as those illustrated in FIGS. 3A to 3D and FIG. 4A, and in which the resist 212 having the opening 212a from which the top surface 31a of the projection 31 is exposed, is laminated on the surface of the copper plate 200 on the projection 31 side.

Subsequently, as illustrated in FIG. 9B, the Ni layer 34 is formed on the top surface 31a of the projection 31 exposed from the opening 212a, by, for example, the electrolytic plating method or the electroless plating method, with the use of the resist 212 as a mask. The electrolytic plating or the electroless plating is performed under a usual reaction condition, that is, a condition in which plating reactions almost equivalent to each other are generated in the central area and the peripheral area. Therefore, the Ni layer 34 having an approximately uniform thickness across the central area and the peripheral area, is formed.

Subsequently, as illustrated in FIG. 9C, the Au layer 36 is formed on the surface of the Ni layer 34 exposed from the opening 212a, by, for example, the electrolytic plating method or the electroless plating method with the use of the resist 212 as a mask. The electrolytic plating or the electroless plating in this case is performed under a condition in which a plating reaction in the peripheral area on the top surface 31a of the projection 31 is suppressed. Thereby, the Au layer 36 having a curved shape, the thickness of the peripheral area of which is smaller than that of the central area, is formed on the Ni layer 34. Thereby, the metallic layer 32 consisting of the Ni/Au layers is formed on the projection 31, allowing the bump electrode 30 having an approximately convex-shaped top surface to be completed.

Subsequently, as illustrated in FIG. 9D, the resist 212 is peeled off with a parting agent. The bump electrode 30 is formed integrally with the copper plate 200 by the processes described above. Thereafter, the copper plate 200, the insulating resin layer 10 and the semiconductor substrate 310 are integrated together; the wiring layer 20 is formed; the protective layer 40 is laminated; the solder ball 50 is provided; and the semiconductor substrate 310 is individuated into the semiconductor modules 1. The semiconductor module 1 can be manufactured by the aforementioned processes.

As stated above, the same advantage as Embodiment 1 can be obtained by Embodiment 3.

### Embodiment 4

In the aforementioned Embodiment 1, the metallic layer 32 consists of multiple layers, and the surface of the Ni layer 34, which is in contact with the projection 31, is approximately convex-shaped and the peripheral area on the surface is curve-shaped; however, the top surface 31a of the projection 31 may be approximately convex-shaped. Hereinafter, the present embodiment will be described. The basic structure of the semiconductor module 1 is basically the same as the Embodiment 1. Therefore, the same structures as Embodiment 1 shall be denoted by the same reference numerals, and the duplicative explanations will be omitted appropriately, and descriptions will be made focusing on the structures different from Embodiment 1.

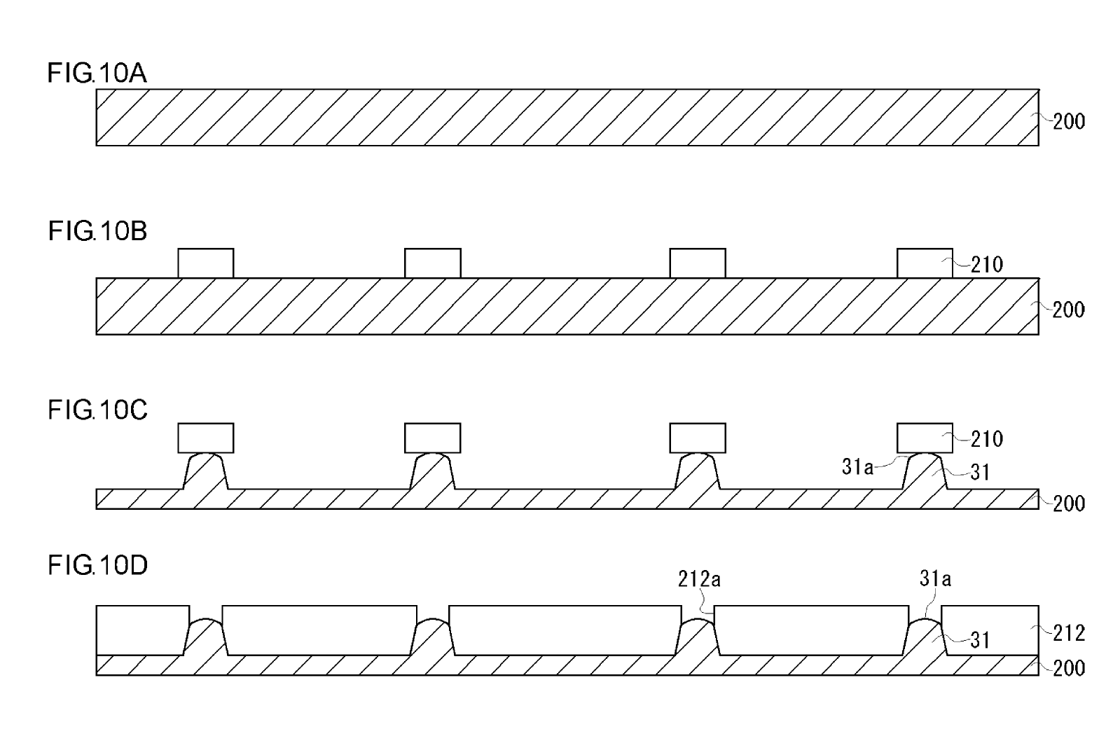

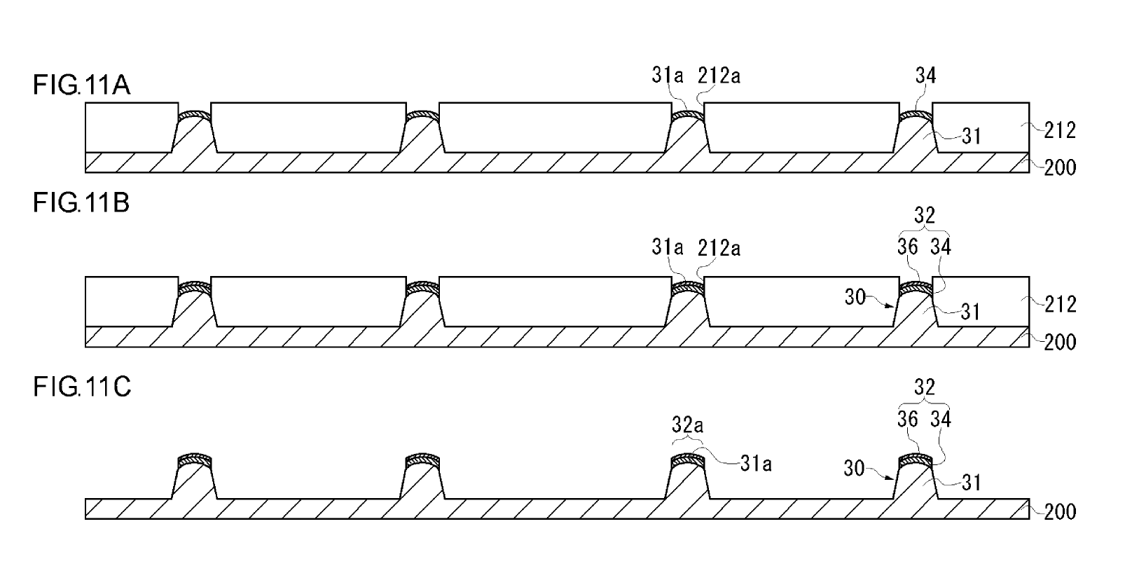

FIGS. 10A to 10D and FIGS. 11A to 11C C are process sectional views illustrating a manufacturing method of a semiconductor module according to Embodiment 4.

As illustrated in FIG. 11C, the bump electrode 30 according to the present embodiment includes the projection 31 and the metallic layer 32, the metallic layer 32 consisting of the Ni layer 34 and the Au layer 36. The top surface 31a of the projection 31 is approximately convex-shaped, and at least the peripheral area on the surface is curve-shaped.

Subsequently, a method of manufacturing the semiconductor module 1 that has the bump electrode 30 having the aforementioned shape, will be described. As illustrated in FIG. 10A, the copper plate 200 having a thickness larger than at least a total of the height of the projection 31 of the bump electrode 30 and the thickness of the wiring layer 20, is at first prepared as a metal plate.

Subsequently, as illustrated in FIG. 10B, the resist 210 is selectively formed on one major surface of the copper plate 200 by the photolithographic method in line with the pattern corresponding to the bump electrode 30 formation areas.

Subsequently, as illustrated in FIG. 10C, the projection 31 having a predetermined truncated cone pattern, projected from the major surface of the copper plate 200, is formed by performing wet-etching on the copper plate 200, with the use of the resist 210 as a mask. In this case, up to the peripheral area that is in contact with the resist 210 of the copper plate 200, is etched by isotropically performing over-etching on the one major surface of the copper plate 200. Thereby, the projection 31 that has an approximately convex-shaped top surface 31a and at least the peripheral area on the top surface 31a is curve-shaped, is formed. The projection 31 can be formed integrally with the copper plate 200 by the aforementioned processes.

Subsequently, as illustrated in FIG. 10D, the resist 210 is peeled off with a parting agent, and then the plating-resistant resist 212 is laminated on the major surface of the copper plate 200 on the side where the projection 31 is formed, so that the projection 31 is buried. Thereafter, the opening 212a is formed by removing a predetermined portion of the resist 212 with the lithographic method or the O₂ plasma etching, etc., so that top surface 31a of the projection 31 is exposed.

Subsequently, as illustrated in FIG. 11 A, the Ni layer 34 is formed, as a metallic layer, on the top surface 31a of the projection 31 exposed from the opening 212a, by, for example, an electrolytic plating method or an electroless plating method with the use of the resist 212 as a mask. The electrolytic plating and the electroless plating are performed under a usual condition, that is, a condition in which plating reactions almost equivalent to each other are generated in the central area and the peripheral area. Thereby, the Ni layer 34 having an approximately uniform thickness across the central area and the peripheral area, is formed on the top surface 31a.

Subsequently, as illustrated in FIG. 11B, the Au layer 36 is formed, as a metallic layer, on the surface of the Ni layer 34 exposed from the opening 212a, by, for example, an electrolytic plating method or an electroless plating with the use of the resist 212 as a mask. The electrolytic plating and the electroless plating are performed under a usual condition, that is, a condition in which plating reactions almost equivalent to each other are generated in the central area and the peripheral area. Thereby, the Au layer 36 having an approximately uniform thickness across the central area and the peripheral area, is laminated on the surface of the Ni layer 34. Thereby, the metallic layer 32 consisting of the Ni/Au layers is formed on the projection 31, allowing the bump electrode 30 having an approximately convex-shaped top surface to be completed.

Subsequently, as illustrated in FIG. 11C, the resist 212 is peeled off with a parting agent. The bump electrode 30 can be formed integrally with the copper plate 200 by the aforementioned processes. The metallic layer 32 may not be laminated on the top surface 31a of the projection 31, and in this case, the projection 31 serves as the bump electrode 30. Thereafter, the copper plate 200, the insulating resin layer 10 and the semiconductor substrate 310 are integrated together; the wiring layer 20 is formed; the protective layer 40 is laminated; the solder ball 50 is provided; and the substrate is individuated into the semiconductor modules 1. The semiconductor module 1 can be manufactured by the processes described above.

As stated above, the same advantage as Embodiment 1 can also be obtained by Embodiment 4.

### Embodiment 5

Subsequently, descriptions will be made with respect to a mobile device provided with the semiconductor module 1 according to the aforementioned respective embodiments. An example in which the semiconductor module 1 is mounted on a cell phone as the mobile device, will be shown; however, the mobile device may be an electronic device including, for example, a Personal Digital Assistant (PDA), a digital camcorder (DVC), and a digital still camera (DSC).

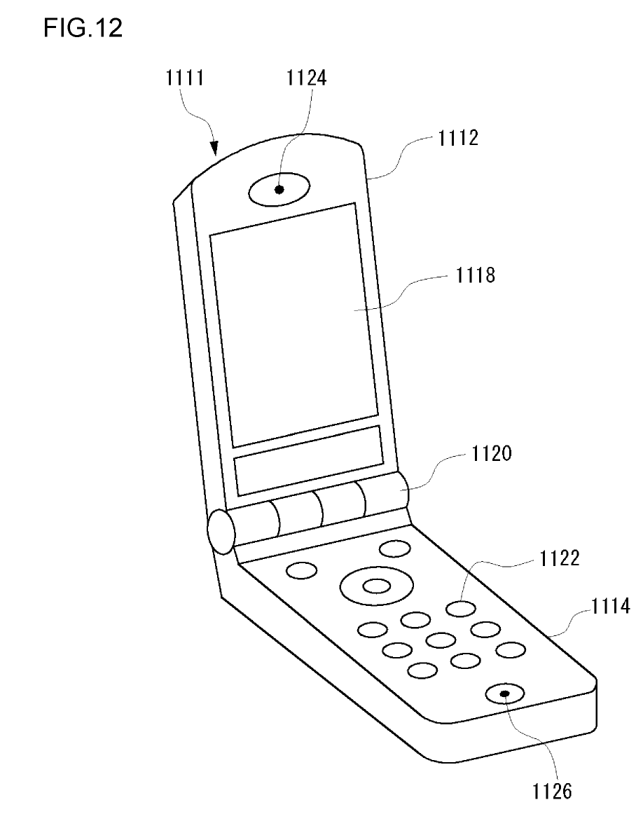

FIG. 12 is a view illustrating the structure of a cell phone according to Embodiment 5. A cell phone 1111 is structured such that a first housing 1112 and a second housing 1114 are connected via a movable part 1120. The first housing 1112 and the second housing 1114 are movable around the movable part 1120. The first housing 1112 is provided with a display unit 1118 for displaying information including characters and images, and with a speaker unit 1124. The second housing 1114 is provided with a control 1122 (e.g. control buttons) and a microphone unit 1126. The semiconductor module according to Embodiment 1 is mounted inside the cell phone 1111 thus structured.

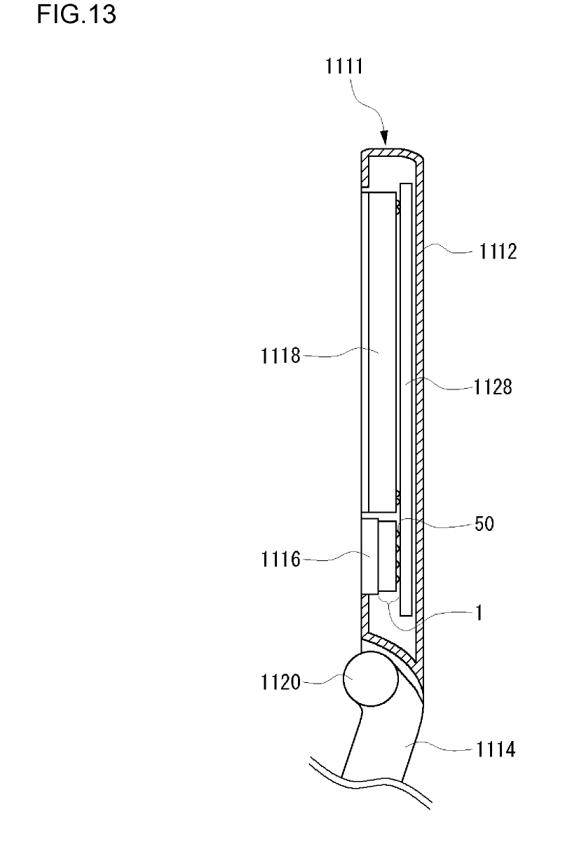

FIG. 13 is a partial cross-sectional view of the cell phone illustrated in FIG. 12 (section of the first housing 1112). The semiconductor module 1 according to the aforementioned respective embodiments is mounted on a printed board 1128 via the solder ball 50 to be electrically connected with the display unit 1118 via the printed board 1128. The underside of the semiconductor module 1 (the surface opposite to the solder ball 50) is provided with a heat spreader 1116 such as a metal plate. For example, heat generated by the semiconductor module 1 is prevented from collected inside the first housing 1112 and is released outside the first housing 1112 efficiently.

According to the semiconductor module 1 directed to each embodiment of the present invention, the connection reliability between the device mounting board 100 and the semiconductor device 300 can be enhanced. Therefore, the operation reliability can be improved in the mobile device according to the present embodiments in which the semiconductor module 1 thus structured is mounted.

The present invention shall not be limited to the aforementioned embodiments, but various modifications such as design modification could be made to the respective embodiments, based on the knowledge of a skilled person. Such modifications could be also within the scope of the present invention.

For example, in the aforementioned respective embodiments, the bump electrode 30 has the approximately convex-shaped top surface 30a, and at least the peripheral area on the top surface 30a is curve-shaped. However, the surface of the device electrode 330 or that of the metallic layer 332 laminated on the device electrode 330, may have such a shape.

What is claimed is:

1. A device mounting board comprising:
an insulating resin layer;
a wiring layer provided on one major surface of the insulating resin layer; and
a bump electrode electrically connected to the wiring layer and configured to be projected from the wiring layer toward the insulating resin layer, wherein the bump electrode has an approximately convex-shaped top surface and at least the peripheral area on the top surface is curve-shaped.

2. The device mounting board according to claim 1, wherein the peripheral area is curve-shaped such that the distance from the surface of the wiring layer on the side where the bump electrode is projected, becomes smaller toward the periphery of the area.

3. The device mounting board according to claim 1, wherein the bump electrode includes a projection connected to the wiring layer and at least one metallic layer laminated on the top surface of the projection, and wherein the surface of the outermost metallic layer opposite to the projection is approximately convex-shaped, and at least the peripheral area on the surface is curve-shaped.

4. The device mounting board according to claim 3, wherein the bump electrode includes two or more of the metallic layers, and wherein the surface of the metallic layer that is in contact with the projection, opposite to the projection, is approximately convex-shaped, and at least the peripheral area on the surface is curve-shaped.

5. A semiconductor module comprising:
a device mounting board provided with an insulating resin layer, a wiring layer provided on one major surface of the insulating resin layer, and a bump electrode electrically connected to the wiring layer and configured to be projected from the wiring layer toward the insulating resin layer; and
a semiconductor device provided with a device electrode connected to the bump electrode, wherein the distance between the bump electrode and the device electrode in the peripheral area of a joint portion between the two electrodes, becomes gradually larger from the joint portion toward outside.

6. A method of manufacturing a device mounting board in which an insulating resin layer and a wiring layer are laminated, the method comprising:
preparing a metal plate for the wiring layer, on one major surface of which a projection is provided; and
forming a bump electrode configured to have an approximately convex-shaped top surface by performing plating on a top surface of the projection under a condition in which a plating reaction in the peripheral area on the top surface is suppressed, with the use of a mask from which the top surface of the projection is opened, so that a metallic layer having a curved shape, the thickness of the peripheral area of which is thinner than that of the central area, is provided on the top surface.

7. A method of manufacturing a semiconductor module, comprising:
forming, on one major surfaces of a metal plate, a bump electrode configured to have an approximately convex-shaped top surface, and configured such that at least the peripheral area on the top surface is curve-shaped;
pressure-bonding, via an insulating resin layer, the metal plate and a semiconductor device provided with a device electrode corresponding to the bump electrode, so that the bump electrode and the device electrode are joined together; and
forming a wiring layer by selectively removing the metal plate.

8. The method of manufacturing a semiconductor module according to claim 7, wherein the forming a bump electrode includes forming a bump electrode having an approximately convex-shaped top surface by preparing a metal plate, on one major surface of which a bump is provided, and by performing plating on the top surface of the bump under a condition in which a plating reaction in the peripheral area on the top surface is suppressed with the use of a mask from which the top surface of the bump is exposed, so that a metallic layer having a curved shape, the thickness in the peripheral area of which is thinner than that in the central area thereof, is provided on the top surface.

9. The method of manufacturing a semiconductor module according to claim 7, wherein the forming a bump electrode includes forming a bump electrode having an approximately convex-shaped top surface by isotropically over-etching one major surface of a metal plate, with the use of a resist laminated at a predetermined position on the one major surface of the metal plat as a mask.

10. The method of manufacturing a semiconductor module according to claim 7, wherein, in the press-bonding, the bump electrode and the device electrode are joined together in a way that the bump electrode penetrates the insulating resin layer to reach the surface of the device electrode, and a joint portion between the two electrodes expands from the central area of the joint portion toward the peripheral area thereof.
